(19) United States
(12) Patent Application Publication
(10) Pub. No.: US 2022/0418058 A1
(43) Pub. Date: Dec. 29, 2022

(54) ELECTRONIC DEVICE AND METHOD FOR MANUFACTURING ELECTRONIC DEVICE

(71) Applicants: PIONEER CORPORATION, Bunkyo-ku, Tokyo (JP); TOHOKU PIONEER CORPORATION, Tendo-shi, Yamagata (JP)

(72) Inventor: Hidetaka OHAZAMA, Yonezawa-shi, Yamagata (JP)

(21) Appl. No.: 17/797,792

(22) PCT Filed: Feb. 8, 2021
(86) PCT No.: PCT/JP2021/004526

§ 371 Date: Aug. 5, 2022

(30) Foreign Application Priority Data
Feb. 10, 2020 (JP) 2020-020809

(51) Int. Cl. H05B 33/06; H05B 33/22; H01L 51/50

(52) U.S. Cl. CPC H05B 33/06; H05B 33/22; H01L 51/50; H05K 1/14

(57) ABSTRACT

A first electronic component (10) includes a terminal (142) and a substrate (100). The substrate (100) includes the terminal (142). At least a portion of a second electronic component (20) overlaps the terminal (142) of the first electronic component (10). A resin film (300) electrically connects the terminal (142) of the first electronic component (10) and the second electronic component (20). The resin film (300) includes a first portion (310) and a second portion (320). The first portion (310) of the resin film (300) overlaps the terminal (142) and the second electronic component (20) when viewed from a predetermined direction (D). The second portion (320) of the resin film (300) does not overlap the substrate (100) or the terminal (142), and overlaps the second electronic component (20) when viewed from the predetermined direction (D).

### TECHNICAL FIELD

The present invention relates to an electronic device and a method for manufacturing the electronic device.

### BACKGROUND ART

A terminal of a first electronic component of a light-emitting device or the like and a second electronic component of a Flexible Printed Circuit (FPC) or the like are sometimes electrically connected through a resin film such as an anisotropic conductive film (ACF), an anisotropic conductive adhesive (ACA), and an anisotropic conductive resin paste (ACP), or the like. Currently, various studies have been made regarding electrically connecting the terminal of the first electronic component and the second electronic component through the resin film.

Patent Document 1 describes an anisotropic conductive tape. This anisotropic conductive tape includes a region having a configuration which is appropriate for COG (Chip-On-Glass)-mounting a semiconductor chip such as a driver integrated circuit (IC) or the like on a substrate for a liquid crystal display (LCD) and a region having a configuration which is appropriate for FOG (Film-On-Glass)-mounting FPC on a substrate for LCD.

Patent Document 2 describes one example of ACF. This ACF includes a first resin composition which does not include any conductive particles and a second resin composition in which conductive particles are scattered, the second resin composition overlapping the first resin composition. An end portion of the first resin composition protrudes further outward than an end portion of the second resin composition. In a case of joining a glass substrate such as LCD or the like to a wiring material such as FPC or the like by using this ACF, the end portion of the first resin composition of the ACF overlaps a boundary between a region of the wiring material to which a protection member such as a solder resist or the like is provided and a region of the wiring material which is exposed from the protection member. Patent Document 2 describes that, when thermocompression bonding is performed on the ACF, the conductive particles are prevented from being stuck between the glass substrate and the solder resist of the wiring material.

### RELATED ART DOCUMENTS

### Patent Documents

[Patent Document 1] WO/2008/029580
[Patent Document 2] Japanese Unexamined Patent Application Publication No. 2011-49175

### SUMMARY OF THE INVENTION

### Technical Problem

When a terminal of a first electronic device such as a light-emitting device or the like and a second electronic component such as FPC or the like through a resin film such as ACF, ACA, and ACP or the like are electrically connected, protection coating to cover an end of the resin film may be provided for various purposes, for example, an improvement of peeling strength between the terminal of the first electronic device and the second electronic component, reduction of a disconnection of the second electronic component, and reduction of corrosion of the terminal of the first electronic device by moisture intrusion or the like. However, providing protection coating separately from the resin film may increase manufacturing costs of the electronic device due to various factors, for example, a cost of materials of the protection coating, and a cost of a device for providing the protection coating or the like. Further, providing the protection coating separately from the resin film may lengthen manufacturing time of the electronic device due to the various factors, for example, an addition of a step of providing the protection coating or the like.

An example of a problem to be solved by the present invention is to reduce costs and time for electrically connecting a terminal of a first electronic device such as a light-emitting device and a second electronic component such as FPC or the like through a resin film such as ACF, ACA, and ACP.

### Solution to Problem

The invention described in claim 1 is an electronic device including:

a first electronic component including a terminal and a substrate including the terminal;

a second electronic component at least a portion of which overlaps the terminal of the first electronic component; and

a resin film electrically connecting the terminal of the first electronic component and the second electronic component,

in which the resin film includes:

a first portion overlapping the terminal and the second electronic component when viewed from a direction perpendicular to a first surface of the substrate; and

a second portion which does not overlap the substrate or the terminal, and overlaps the second electronic component when viewed from the direction perpendicular to the first surface of the substrate.

The invention described in claim 8 is a method for manufacturing an electronic device, the method including:

causing a terminal of a substrate of a first electronic component and at least a portion of a second electronic component to overlap each other with a resin composition interposed therebetween; and

electrically connecting the terminal of the first electronic component and the second electronic component through a resin film formed by curing the resin composition,

in which in the step of causing the terminal of the first electronic component and at least the a portion of the second electronic component to overlap each other, when viewed from a direction perpendicular to a first surface of the substrate, a first portion of the resin composition is overlapped with the terminal and the second electronic component, and a second portion of the resin composition is not overlapped with the substrate or the terminal and is overlapped with the second electronic component.

The invention described in claim 9 is a method for manufacturing an electronic device, the method including:

causing a terminal of a substrate of a first electronic component and at least a portion of a second electronic component to overlap each other with a resin composition interposed therebetween; and

electrically connecting the terminal of the first electronic component and the second electronic component through a resin film formed by curing the resin composition,

in which in the step of causing the terminal of the first electronic component and at least the a portion of the second electronic component to overlap each other, when viewed from a direction perpendicular to a first surface of the substrate, a first portion and a second portion of the resin composition which have different viscosities are overlapped with each other, and the first portion and the second portion of the resin composition are overlapped with the terminal and the second electronic component.

### BRIEF DESCRIPTION OF THE DRAWINGS

FIG. 1 is a plan view of an electronic device according to the embodiment.

FIG. 2 is a cross-sectional view taken along line A-A of FIG. 1.

FIG. 3 is a cross-sectional view taken along line B-B of FIG. 1.

FIG. 4 is a plan view of one example of a resin composition used in a method for manufacturing the electronic device illustrated in FIGS. 1-3.

FIG. 5 is a cross-sectional view taken along line P-P of FIG. 4.

FIG. 6 is a diagram to explain one example of a method for manufacturing the electronic device using the resin composition illustrated in FIG. 4 and FIG. 5.

FIG. 7 is a diagram illustrating a first modification example of FIG. 5.

FIG. 8 is a diagram illustrating a second modification example of FIG. 5.

FIG. 9 is a diagram illustrating a third modification example of FIG. 5.

FIG. 10 is a diagram to explain one example of the method for manufacturing the electronic device using the resin composition illustrated in FIG. 9.

### DESCRIPTION OF EMBODIMENTS

In the present specification, the expression “A is positioned over B” may mean that, for example, A is positioned directly over B without having another element (for example, layer) positioned between A and B, or may mean that another element (for example, layer) is partly or wholly positioned between A and B. In addition, an expression indicating a direction such as “top”, “bottom”, “left”, “right”, “front”, and “rear” or the like is basically used in combination with a direction of a drawing, and it is not limited to be interpreted for, for example, a direction of the use of an invention described in the present specification.

In the present specification, unless otherwise noted, the expression “A and B overlap” means that at least a part of A occupies the same area as at least a part of B in an image projected from a certain direction. At this time, a plurality of elements may be in contact with each other, or may be separated from each other.

In the present specification, unless otherwise noted, the expression “outside of A” means an area where A is not positioned with the edge of A as a boundary.

In the present specification, an anode indicates an electrode which injects an electron hole into a layer (for example, organic layer) including a light-emitting material, and a cathode indicates an electrode which injects an electron into a layer including the light-emitting material. Further, the expressions “anode” and “cathode” may mean other wording such as “electron hole injection electrode” and “electron injection electrode” or “positive electrode” and “negative electrode”, or the like.

In the present specification, the expression “end of A” means a boundary between A and another element when viewed from one direction, the expression “end portion of A” means a partial region of A including the boundary, and the expression “endpoint of A” means a certain point on the boundary.

“Light-emitting device” in the present specification includes a device including a light-emitting element such as a display or illumination or the like. Further, there may be a case where a wiring directly, indirectly, or electrically connected to a light-emitting element, an integrated circuit (IC), a housing, or the like is also included in “light-emitting device”.

In the present specification, unless otherwise noted, it is possible to replace the expression “film” with the expression “layer” according to circumstances and occasions. For example, the wording “insulating film” may be replaced with the wording “insulating layer”.

In the present specification, “connection” indicates a state in which a plurality of elements are being connected regardless of whether they are directly or indirectly connected. For example, even a case where the plurality of elements are connected with an adhesive or a connecting member intervening therebetween may be expressed simply as “a plurality of elements are connected”. Further, a case where a member which is capable of supplying or transmitting current, voltage, or electrical potential exists between the plurality of elements, and “the plurality of elements are electrically connected” may also be expressed simply as “a plurality of elements are connected”.

In the present specification, unless otherwise noted, an expression such as “first, second, A, B, (a), (b)” or the like are intended to distinguish elements, and an essence, an order, a sequence, or a quantity, or the like of the element is not limited by the expression.

In the present specification, each member and each element may be singular, or plural. However, when “singular” or “plural” is clear in a context, it is not limited to this.

In the present specification, unless otherwise noted, a meaning of the expression “A includes B” is not limited to that A is configured only with B, but that A can be configured with elements other than B.

In the present specification, unless otherwise noted, “section” means a surface which appears when a light-emitting device is cut in a direction of a pixel or a light-emitting material or the like being laminated.

In the present specification, expressions such as “does not have”, “does not include”, and “is not positioned” or the like may mean that a certain element is completely excluded or that a certain element exists to a degree at which the element does not have a technical effect.

In the present specification, expressions for explaining a chronological order such as “after”, “subsequently to”, “next to”, and “before” or the like express a relative temporal relationship, and respective elements for which a temporal before-after relationship is used are not necessarily continuous. In order to express that the respective elements are continuous, an expression such as “immediately”, “directly”, or the like may be used.

In the present specification, the expression “to heat A” means that heat is added to A, and it is not limited to heating only A. The expression may mean, for example, that an element including A is heated. Further, “to add heat” means to intentionally or artificially add heat, and a simple change of temperature of an atmosphere in the surroundings of A is not included in the meaning.

In the present specification, unless otherwise noted, the expression “A covers B” may mean that A is in contact with B without another element (for example, layer) interposed between A and B, or may mean that another element (for example, layer) is partly or wholly positioned between A and B.

Embodiments of the present invention will be described below by referring to the drawings. Moreover, in all the drawings, the same constituent elements are given the same reference numerals, and descriptions thereof will not be repeated.

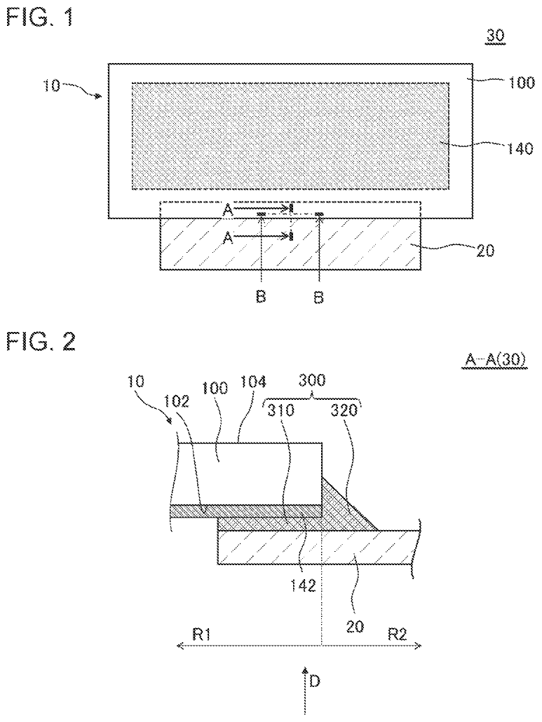

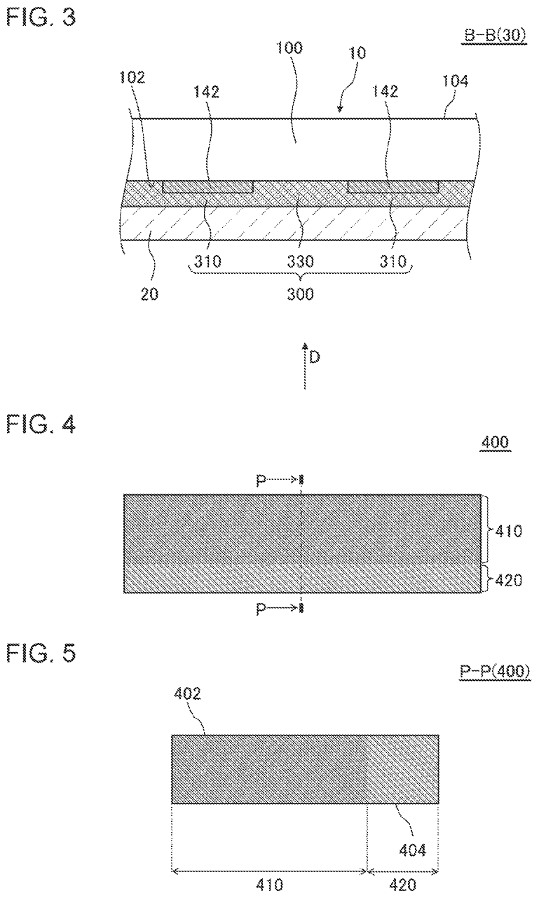

FIG. 1 is a plan view of an electronic device 30 according to the embodiment. FIG. 2 is a cross-sectional view taken along line A-A of FIG. 1. FIG. 3 is a cross-sectional view taken along line B-B of FIG. 1.

Below, an explanation is performed by using terms such as a predetermined direction D, a first region R1, and a second region R2 when necessary. As shown in FIG. 2 and FIG. 3, the predetermined direction D means a direction perpendicular to a first surface 102 of a substrate 100 which will be described later. As shown in FIG. 2, the first region R1 means a region overlapping a terminal 142 which will be described later when viewed from the predetermined direction D. As shown in FIG. 2, the second region R2 means a region which overlaps a second electronic component 20, which will be described later, without overlapping the substrate 100 when viewed from the predetermined direction D.

A summary of an electronic device 30 will be explained using FIGS. 1-3. The electronic device 30 includes a first electronic component 10, a second electronic component 20, and a resin film 300. The first electronic component 10 includes the terminal 142 and the substrate 100. The substrate 100 includes the terminal 142. At least a portion of the second electronic component 20 overlaps the terminal 142 of the first electronic component 10. The resin film 300 electrically connects the terminal 142 of the first electronic component 10 and the second electronic component 20. The resin film 300 includes a first portion 310, a second portion 320, and a third portion 330. The first portion 310 of the resin film 300 overlaps the terminal 142 and the second electronic component 20 when viewed from the predetermined direction D. The second portion 320 of the resin film 300 does not overlap the substrate 100 or the terminal 142, and overlaps the second electronic component 20 when viewed from the predetermined direction D. The third portion 330 of the resin film 300 does not overlap the terminal 142, and overlaps the substrate 100 and the second electronic component 20 when viewed from the predetermined direction D.

According to the present embodiment, the second portion 320 of the resin film 300 can function as a protection coating. That is, in a case where the second portion 320 of the resin film 300 is provided, in comparison with a case where the second portion 320 of the resin film 300 is not provided, for example, peeling strength between the terminal 142 of the first electronic component 10 and the second electronic component 20 is improved, disconnection of the second electronic component 20 is reduced, and corrosion of the terminal 142 of the first electronic device 10 by moisture intrusion is reduced. In addition, in the present embodiment, the protection coating need not be provided separately from the resin film 300. Therefore, in the present embodiment, in comparison with a case where the protection coating is provided separately from the resin film 300, it is possible to reduce costs and time for electrically connecting the terminal 142 of the first electronic component 10 and the second electronic component 20 through the resin film 300.

In the present embodiment, the first electronic component 10 is a light-emitting device including an organic electroluminescence (EL) element 140. However, the first electronic component 10 may be a light-emitting device including an inorganic EL element. Alternatively, the first electronic component 10 may be a light-emitting device such as a liquid crystal display (LCD) panel or the like. Alternatively, the first electronic component 10 may be a semiconductor device such as a printed circuit board (PCB) or the like.

In the present embodiment, the second electronic component 20 is a Flexible Printed Circuit (FPC). However, the second electronic component 20 may be a semiconductor device such as a semiconductor chip or the like. In a case where the second electronic component 20 is the semiconductor device, the second electronic component 20 may be, for example, a driver integrated circuit (IC) which drives the first electronic component 10.

Below, using FIG. 1 to FIG. 3, a description will be provided assuming that the first electronic component 10 is a light-emitting device including the organic EL element 140, and that the second electronic component 20 is FPC. As is clear from a description below, even in a case where the first electronic component 10 and the second electronic component 20 are different from an electronic component according to the present embodiment, the terminal of the substrate of the first electronic component 10 and the second electronic component 20 can be electrically connected through the resin film 300.

The substrate 100 may be single-layered or multi-layered. A thickness of the substrate 100 is, for example, equal to or greater than 10 μm and equal to or less than 1,000 μm. The substrate 100 includes the first surface 102 and a second surface 104. In the present embodiment, the first surface 102 of the substrate 100 is a surface facing the second electronic component 20 which is connected to the terminal 142. The second surface 104 is on the opposite side to the first surface 102. The substrate 100 is, for example, a glass substrate. The substrate 100 may be a resin substrate including an organic material (for example, polyethylene naphthalate (PEN), polyether sulphone (PES), polyethylene terephthalate (PET), or polyimide). In a case where the substrate 100 is a resin substrate, an inorganic barrier layer (for example, SiN or SiON) may be positioned over at least one of the first surface 102 and the second surface 104 of the substrate 100.

The organic EL element 140 includes the anode, the cathode, and the organic layer between the anode and the cathode. The anode, the organic layer, and the cathode are positioned over the first surface 102 of the substrate 100, and laminated in order from the first surface 102 side of the substrate 100. The organic layer includes, for example, a hole injection layer (HIL), a hole transport layer (HTL), a light-emitting layer (EML), an electron transport layer (HTL), and a hole injection layer (HIL) in this order from the anode toward the cathode.

In the present embodiment, the organic EL element 140 is a bottom-emission type. That is, the light emitted from the organic EL element 140 is transmitted through the substrate 100 and irradiated toward the outside of the electronic device 30 from the second surface 104 side of the substrate 100. However, the organic EL element 140 may be a top-emission type. Further, the light emitted from the organic EL element 140 may be irradiated from both of the first surface 102 side of the substrate 100 and the second surface 104 side of the substrate 100.

In the present embodiment, the organic EL element 140 is a surface light source. In this case, the first electronic component 10 is a light-emitting panel. For example, the anode which spreads in a planar shape such as a rectangle or the like and the cathode which spreads in a planar shape such as a rectangle or the like are overlapped with each other. However, an aspect of the organic EL element 140 is not limited to this. For example, a plurality of the organic EL elements 140 may be arranged in a matrix shape. In this case, the first electronic component 10 is a light-emitting display. For example, a plurality of anodes arranged in a stripe shape and a plurality of cathodes arranged in a stripe shape intersect each other. In this case, an intersection portion of these anodes and cathodes is a pixel, that is, the organic EL element 140. Alternatively, the plurality of the organic EL elements 140 may be arranged in a stripe shape.

For example, a plurality of light-transmitting anodes arranged in a stripe shape and a plurality of light-shielding cathodes arranged in a stripe shape are overlapped with each other. In this case, light can be transmitted through a region between the cathodes which are adjacent to each other.

In this case, the first electronic component 10 is a light-transmitting-type light-emitting panel.

The terminal 142 is electrically connected to the organic EL element 140. For example, the terminal 142 is connected to the anode or the cathode of the organic EL element 140. Thus, the organic EL element 140 is electrically connected to an external device of the electronic device 30, for example, a power supply of the electronic device 30 through the terminal 142 and the second electronic component 20.

In the present specification, the organic EL element 140 and the terminal 142 are positioned on a common surface side of the substrate 100, that is, the first surface 102 side. However, the organic EL element 140 and the terminal 142 may be positioned on different surface sides of the substrate 100. For example, the organic EL element 140 may be positioned on the second surface 104 side of the substrate 100, and the terminal 142 may be positioned on the first surface 102 side of the substrate 100.

When viewed from the predetermined direction D, a portion of the second electronic component 20, that is, an end portion overlaps a portion of the substrate 100, that is, an end portion. Noted that, for example, when the first electronic component 10 is a semiconductor device such as PCB or the like and the second electronic component 20 is a semiconductor device such as the semiconductor chip or the like, when viewed from the predetermined direction D, the entirety of the second electronic component 20 may be overlapped with the first electronic component 10.

The resin film 300 is a cured product of a resin composition 400 described later. For example, the resin film 300 is the cured product of ACF, ACA, or ACP. The resin film 300 includes, for example, the cured product of a thermosetting resin and conductive particles scattered in this cured product. The resin film 300 may further appropriately include a curing agent and an additive. Note that the resin film 300 may include the cured product of a photocurable resin instead of the cured product of the thermosetting resin, or, along with the cured product of the thermosetting resin. Further, the resin film 300 need not include the conductive particles and may include a conductive resin which is capable of electrically connecting the terminal 142 and the second electronic component 20.

The thermosetting resin used for the cured product included in the resin film 300 is, for example, an epoxy resin such as a solid epoxy resin, and a liquid epoxy resin or the like. The solid epoxy resin may be a bisphenol A type epoxy resin or the like. The liquid epoxy resin may be a bisphenol type epoxy resin or the like. These may be used independently, or two kinds or more may be used in combination.

A conductive particle included in the resin film 300 is, for example, a metal particle such as gold, silver, or the like, or a carbon particle. Alternately, the conductive particle may be an insulating particle such as a resin particle or the like covered by a conductive material such as a metal or the like. Further, the conductive particle may be covered by an insulating film.

The resin film 300 includes the cured product which continues across the first portion 310, the second portion 320, and the third portion 330. “Continues” means, for example, that the first portion 310, the second portion 320, and the third portion 330 include a common cured product, and that an interface of two materials does not exist between respective portions. A reason why the cured product continues is, as described in detail later, that the first portion 310, the second portion 320, and the third portion 330 of the resin film 300 are formed using a common resin composition 400.

The first position 310 of the resin film 300 includes the conductive particles. Thus, the first position 310 of the resin film 300 has conductivity. Therefore, the terminal 142 of the first electronic component 10 and the second electronic component 20 are electrically connected through the first portion 310 of the resin film 300.

As shown in FIG. 2, the second portion 320 of the resin film 300 covers a portion of the side surface of the substrate 100 positioned over a boundary between the first region R1 and the second region R2. In this case, in comparison with a case where the second portion 320 of the resin film 300 does not cover the side surface of the substrate 100, the second portion 320 of the resin film 300 can more certainly function as the protection coating. However, the second portion 320 of the resin film 300 need not cover the side surface of the substrate 100.

A density of conductive particles of the second portion 320 of the resin film 300 is lower than a density of conductive particles of the first portion 310 of the resin film 300. Therefore, in a thickness direction of the resin film 300, that is, the predetermined direction D, a conductivity of the second portion 320 of the resin film 300 is lower than a conductivity of the first portion 310 of the resin film 300. As described later, the second portion 320 of the resin film 300 substantially may not include the conductive particles. In this case, the second portion 320 of the resin film 300 substantially has electrical insulating properties.

In a case where the density of the conductive particles of the second portion 320 of the resin film 300 is lower than the density of the conductive particles of the first portion 310 of the resin film 300, in comparison with a case where the density of the conductive particles of the second portion 320 of the resin film 300 is equal to or greater than the density of the conductive particles of the first portion 310 of the resin film 300, it is possible to reduce manufacturing costs of the electronic device 30 by an amount corresponding to reduced conductive particles, and it is possible to reduce a possibility of a short circuit between the first electronic component 10 and the second electronic component 20 through the second portion 320 of the resin film 300. Particularly, even in a case where the second portion 320 of the resin film 300 covers a portion of the side surface the substrate 100, it is possible to reduce a possibility of a short circuit between the side surface of the substrate 100 and the second electronic component 20 through the second portion 320 of the resin film 300. However, the second portion 320 of the resin film 300 may include the conductive particles. For example, the density of the conductive particles of the second portion 320 of the resin film 300 may be equal to or greater than the density of the conductive particles of the first portion 310 of the resin film 300.

A density of the conductive particles of the third portion 330 of the resin film 300 is lower than the density of the conductive particles of the first portion 310 of the resin film 300. Therefore, in the thickness direction of the resin film 300, that is, the predetermined direction D, a conductivity of the third portion 330 of the resin film 300 is lower than the conductivity of the first portion 310 of the resin film 300. Thus, it is possible to prevent a short circuit through the third portion 330 of the resin film 300.

For example, the third portion 330 of the resin film 300 substantially has electrical insulating properties.

The density of the conductive particles of each portion of the resin film 300 may be determined based on, for example, the number of the conductive particles per unit area on a cross section, of each portion of the resin film 300, which passes through in a direction parallel to the thickness direction of the resin film 300, that is, a cross section, of each portion of the resin film 300, which passes through in a direction parallel to the predetermined direction D. This cross section may be, for example, the cross section taken along line A-A of FIG. 2, or the cross section taken along line B-B of FIG. 3. For example, an image of a cross section formed by cutting each portion of the resin film 300 along the direction in parallel to the predetermined direction D is acquired by a microscope such as a Scanning Electron Microscope (SEM), and the number of conductive particles per unit area in the cross section is calculated based on the number of the conductive particles displayed on the image.

The number of the conductive particles per unit area is, for example, equal to or greater than 200 pieces/mm² on the above cross section of the first portion 310 of the resin film 300.

The number of the conductive particles per unit area on the above cross section of the second portion 320 of the resin film 300 is, for example, equal to or less than 50 pieces/mm². Particularly, in a case where the number of the conductive particles per unit area on the above cross section of the second portion 320 of the resin film 300 is equal to or less than 10 pieces/mm², it can be said that the second portion 320 of the resin film 300 substantially does not include the conductive particles.

The number of the conductive particles per unit area on the above cross section of the third portion 330 of the resin film 300 is, for example, equal to or greater than 100 pieces/mm².

FIG. 2 illustrates a cross section which passes through both of the first portion 310 and the second portion 320 of the resin film 300. On a cross section which is different from the cross section illustrated in FIG. 2, for example, a cross section which is in parallel to the cross section illustrated in FIG. 2 and passes through both of the third portion 330 and the second portion 320 of the resin film 300, the second portion 320 of the resin film 300 may or may not cover the side surface of the substrate 100. Further, on the above cross section which is different from the cross section illustrated in FIG. 2, the resin film 300 need not spread to the second region R2, and need not have a portion corresponding to the second portion 320.

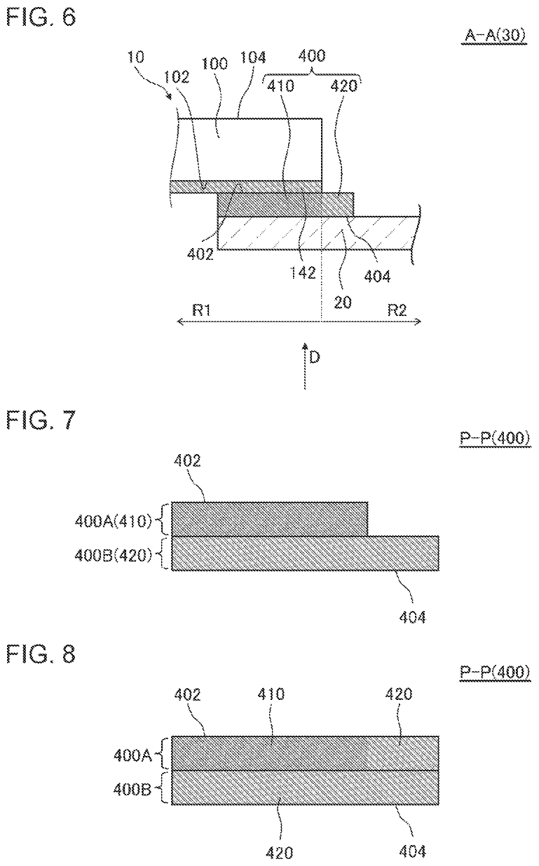

FIG. 4 is a plan view of one example of the resin composition 400 used in a method for manufacturing the electronic device 30 illustrated in FIGS. 1-3. FIG. 5 is a cross-sectional view taken along line P-P of FIG. 4. FIG. 6 is a diagram to explain one example of the method for manufacturing the electronic device 30 using the resin composition 400 in FIG. 4 and FIG. 5.

A summary of the method for manufacturing the electronic device 30 will be explained using FIG. 2 and FIG. 6. First, as shown in FIG. 6, the terminal 142 of the substrate 100 of the first electronic component 10 and at least the portion of the second electronic component 20 are caused to overlap each other with the resin composition 400 interposed therebetween. Then, through the resin film 300 formed by curing the resin composition 400, the terminal 142 of the first electronic component 10 and the second electronic component 20 are electrically connected.

In the above manner, the electronic device 30 illustrated in FIG. 2 is manufactured. In the step of causing the terminal 142 of the first electronic component 10 and at least the portion of the second electronic component 20 to overlap each other, when viewed from the predetermined direction D, a first portion of the resin composition 400 is overlapped with the terminal 142 and the second electronic component 20, and a second portion of the resin composition 400 is not overlapped with the substrate 100 or the terminal 142 and is overlapped with the second electronic component 20.

In the present embodiment, the above second portion of the resin composition 400 is the second portion 320 of the resin film 300, that is, the protection coating. Therefore, in the present embodiment, it is not necessary to provide the protection coating separately from the resin composition 400. Thus, in the present embodiment, in comparison with a case where the protection coating is provided separately from the resin composition 400, it is possible to reduce the costs and time for electrically connecting the terminal 142 of the first electronic component 10 and the second electronic component 20 through the resin film 300.

Details of the resin composition 400 will be explained using FIGS. 4-6.

The resin composition 400 is ACF, ACA, or ACP. The resin composition 400 becomes the resin film 300 through curing of the resin composition 400. The resin composition 400 includes the thermosetting resin and the conductive particles. The resin composition 400 may further appropriately include the curing agent and the additive. The thermosetting resin, the conductive particles, the curing agent, and the additive with respect to the resin composition 400 are the same as the thermosetting resin, the conductive particles, the curing agent, and the additive with respect to the resin film 300 respectively. Note that the resin composition 400 may include the photocurable resin instead of the thermosetting resin, or, with the thermosetting resin. In this case, the resin composition 400 becomes the resin film 300 through photocuring of the resin composition 400.

The resin composition 400 includes a third surface 402 and a fourth surface 404. As shown in FIG. 6, the third surface 402 of the resin composition 400 is a surface facing the first electronic component 10 in a case where the terminal 142 of the first electronic component 10 and at least the portion of the second electronic component 20 are caused to overlap each other with the resin composition 400 interposed therebetween. The fourth surface 404 of the resin composition 400 is on the opposite side to the third surface 402 of the resin composition 400. The fourth surface 404 of the resin composition 400 is a surface facing the second electronic component 20 in a case where the terminal 142 of the first electronic component 10 and at least the portion of the second electronic component 20 are caused to overlap each other with the resin composition 400 interposed therebetween.

The resin composition 400 includes a conductive particle containing portion 410 and a resin containing portion 420. The conductive particle containing portion 410 of the resin composition 400 includes the thermosetting resin and the conductive particles scattered in this thermosetting resin. The resin containing portion 420 of the resin composition 400 includes the thermosetting resin. In the present embodiment, in a direction from the conductive particle containing portion 410 to the resin containing portion 420, a length of the conductive particle containing portion 410 is longer than a length of the resin containing portion 420. Further, the resin containing portion 420 may be a material having a moisture permeability which is lower than the conductive particle containing portion 410. However, a relationship between the length of the conductive particle containing portion 410 and the length of the resin containing portion 420 is not limited to a relationship according to the present embodiment.

A density of conductive particles of the resin containing portion 420 of the resin composition 400 is lower than a density of conductive particles of the conductive particle containing portion 410 of the resin composition 400. As described later, the resin containing portion 420 of the resin composition 400 substantially may not include the conductive particles.

A density of the conductive particles of each portion of the resin composition 400 may be determined based on, for example, the number of the conductive particles per unit area of the resin composition 400 when viewed from a direction parallel to the thickness direction of the resin composition 400, that is, when viewed from the predetermined direction D. For example, an image of each portion of the resin composition 400 is acquired by a microscope such as an optical microscope or the like, and the number of conductive particles per unit area in each portion of the resin composition 400 is determined based on the number of the conductive particles displayed on the image.

The number of the conductive particles per unit area of the conductive particle containing portion 410 of the resin composition 400 when viewed from the direction parallel to the thickness direction of the resin composition 400 is, for example, equal to or greater than 10,000 pieces/mm².

The number of the conductive particles per unit area of the resin containing portion 420 of the resin composition 400 when viewed from the direction parallel to the thickness direction of the resin composition 400 is, for example, equal to or less than 1,000 pieces/mm². Alternately, when viewed from the direction parallel to the thickness direction of the resin composition 400, the number of the conductive particles per unit area of the resin containing portion 420 of the resin composition 400 is, for example, equal to or less than one tenth of the number of the conductive particles per unit area of the conductive particle containing portion 410 of the resin composition 400. Particularly, in a case where the number of the conductive particles per unit area of the resin containing portion 420 of the resin composition 400 when viewed from the direction parallel to the thickness direction of the resin composition 400 is equal to or less than 1,000 pieces/mm², it can be said that the resin containing portion 420 of the resin composition 400 substantially does not include the conductive particles. Alternately, when viewed from the direction parallel to the thickness direction of the resin composition 400, in a case where the number of the conductive particles per unit area of the resin containing portion 420 of the resin composition 400 is equal to or less than one tenth of the number of the conductive particles per unit area of the conductive particle containing portion 410 of the resin composition 400, it can be said that the resin containing portion 420 of the resin composition 400 does not substantially include the conductive particles.

The resin composition 400 is formed by, for example, electively introducing the conductive particles to a resin composition which does not include the conductive particles. However, a method of forming the conductive particle containing portion 410 and the resin containing portion 420 of the resin composition 400 is not limited to this example.

At least a portion of the above first portion of the resin composition 400 is the conductive particle containing portion 410 of the resin composition 400, and at least a portion of the above second portion of the resin composition 400 is the resin containing portion 420 of the resin composition 400. Specifically, as shown in FIG. 6, the conductive particle containing portion 410 of the resin composition 400 overlaps the terminal 142 of the first electronic component 10 and the second electronic component 20 when viewed from the predetermined direction D, and the resin containing portion 420 of the resin composition 400 does not overlap the substrate 100 or the terminal 142, and overlaps the second electronic component 20 when viewed from the predetermined direction D. In the example shown in FIG. 6, a boundary between the conductive particle containing portion 410 and the resin containing portion 420 of the resin composition 400 matches the boundary between the first region R1 and the second region R2. However, the boundary between the conductive particle containing portion 410 and the resin containing portion 420 of the resin composition 400 may be deviated from the boundary between the first region R1 and the second region R2.

The method for manufacturing the electronic device 30 may further include a step of pressing the resin composition 400 by at least one of the terminal 142 of the first electronic component 10 and at least the portion of the second electronic component 20 such that a thickness of a portion of the resin composition 400 which overlaps the terminal 142 and the second electronic component 20 when viewed from the predetermined direction D is thinner than a thickness of a portion of the resin composition 400 which does not overlap the substrate 100 or the terminal 142 and which overlaps the second electronic component 20 when viewed from the predetermined direction D. By doing this way, as shown in FIG. 2, it is possible to allow the second portion 320 of the resin film 300 to cover the portion of the side surface of the substrate 100.

The resin composition 400 can be formed into the resin film 300 by, for example, thermocompression. That is, it is possible to cure the resin composition 400 by pressing the resin composition 400 by at least one of the terminal 142 of the first electronic component 10 and at least the portion of the second electronic component 20 while heating the resin composition 400.

In the present embodiment, the density of the conductive particles of the resin containing portion 420 of the resin composition 400 is lower than the density of the conductive particles of the conductive particle containing portion 410 of the resin composition 400. However, the density of the conductive particles of the resin containing portion 420 of the resin composition 400 may be equal to or higher than the density of the conductive particles of the conductive particle containing portion 410 of the resin composition 400. In this case also, in the step of causing the terminal 142 of the first electronic component 10 and at least the portion of the second electronic component 20 to overlap each other, the first portion of the resin composition 400 is overlapped with the terminal 142 and the second electronic component 20 when viewed from the predetermined direction D, and the second portion of the resin composition 400 is not overlapped with the substrate 100 or the terminal 142, and is overlapped with the second electronic component 20 when viewed from the predetermined direction D. In this case, the above second portion of the resin composition 400 is the second portion 320 of the resin film 300, that is, the protection coating.

FIG. 7 is a diagram illustrating a first modification example of FIG. 5.

The resin composition 400 includes a first layer 400A and a second layer 400B. The first layer 400A and the second layer 400B are arranged from the third surface 402 toward the fourth surface 404 of the resin film 300. Further, the first layer 400A is the conductive particle containing portion 410. The conductive particle containing portion 410 includes the thermosetting resin and the conductive particle. The second layer 400B is the resin containing portion 420. The resin containing portion 420 includes the thermosetting resin, and substantially does not include the conductive particles. An end portion of the resin containing portion 420 protrudes further outward than the end portion of the conductive particle containing portion 410. The resin composition 400 is formed by, for example, laminating a resin composition including the conductive particles on a resin composition which does not include the conductive particles.

In the present modification example also, in the step of causing the terminal 142 of the first electronic component 10 and at least the portion of the second electronic component 20 to overlap each other, when viewed from the predetermined direction D, the conductive particle containing portion 410 of the resin composition 400 is overlapped with the terminal 142 and the second electronic component 20, together with a portion of the resin containing portion 420 which overlaps the conductive particle containing portion 410, and a portion of the resin containing portion 420 of the resin composition 400, that is, a portion of the resin containing portion 420 which does not overlap the conductive particle containing portion 410 is not overlapped with the substrate 100 or the terminal 142, and is overlapped with the second electronic component 20.

In the present modification example, the first layer 400A and the second layer 400B are crushed between the first electronic component 10 and the second electronic component 20 of the resin film 300, and the thermosetting resin and the conductive particles included in the first layer 400A and the thermosetting resin included in the second layer 400B become mixed. Thus, in the first portion 310 of the resin film 300 formed by curing the resin composition 400, the conductive particles are distributed almost uniformly in the cured product of the thermosetting resin.

In the present modification example, the resin composition 400 is used such that the conductive particle containing portion 410 is oriented to the first electronic component 10, and that the resin containing portion 420 is oriented to the second electronic component 20. However, the resin composition 400 may be used such that the conductive particle containing portion 410 is oriented to the second electronic component 20, and that the resin containing portion 420 is oriented to the first electronic component 10.

FIG. 8 is a diagram illustrating a second modification example of FIG. 5.

The resin composition 400 includes the first layer 400A and the second layer 400B. In the same manner as the resin composition 400 shown in FIG. 5, the first layer 400A includes the conductive particle containing portion 410 and the resin containing portion 420. In the same manner as the second layer 400B shown in FIG. 7, the second layer 400B includes the resin containing portion 420. The resin composition 400 is formed by, for example, laminating a resin composition illustrated in FIG. 5 on a resin composition which does not include conductive particles.

In the present modification example also, in the step of causing the terminal 142 of the first electronic component 10 and at least the portion of the second electronic component 20 to overlap each other, when viewed from the predetermined direction D, the conductive particle containing portion 410 of the resin composition 400 is overlapped with the terminal 142 and the second electronic component 20, together with a portion of the second layer 400B which overlaps the conductive particle containing portion 410, and the resin containing portion 420 of the first layer 400A and a portion of the second layer 400B, that is, a portion of the second layer 400B which does not overlap the conductive particle containing portion 410 is not overlapped with the substrate 100 or the terminal 142, and is overlapped with the second electronic component 20.

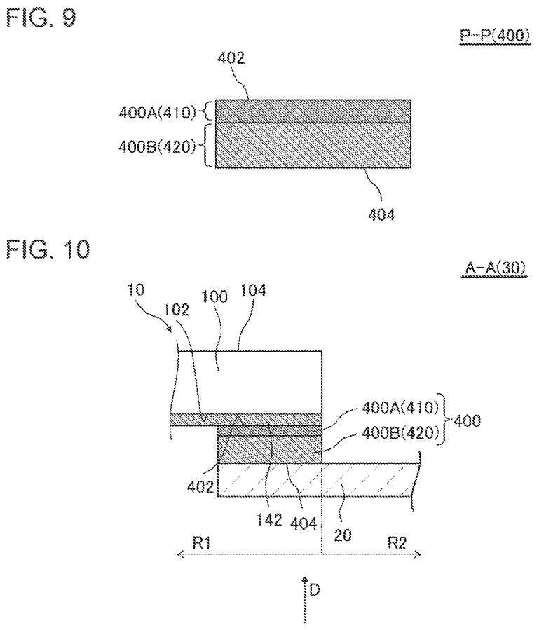

FIG. 9 is a diagram illustrating a third modification example of FIG. 5. FIG. 10 is a diagram to explain one example of the method for manufacturing the electronic device 30 using the resin composition 400 illustrated in FIG. 9.

In the example illustrated in FIG. 10, in the step of causing the terminal 142 of the first electronic component 10 and at least the portion of the second electronic component 20 to overlap each other, when viewed from the predetermined direction D, the first portion and the second portion of the resin composition 400 which have different viscosities are overlapped with each other, and the first portion and the second portion of the resin composition 400 are overlapped with the terminal 142 and the second electronic component 20.

In the present modification example, a portion having a lower viscosity in the above first portion and the above second portion of the resin composition 400 flows out from the first region R1 toward the second region R2, and becomes the second portion 320 of the resin film 300, that is, the protection coating. Therefore, in the present embodiment, it is not necessary to provide the protection coating separately from the resin composition 400. Thus, in the present embodiment, in comparison with a case where the protection coating is provided separately from the resin composition 400, it is possible to reduce the costs and time for electrically connecting the terminal 142 of the first electronic component 10 and the second electronic component 20 through the resin film 300.

Details of the resin composition 400 will be explained using FIG. 9 and FIG. 10.

As shown in FIG. 9, the resin composition 400 includes the first layer 400A and the second layer 400B. The first layer 400A is the conductive particle containing portion 410. The second layer 400B is the resin containing portion 420. The conductive particle containing portion 410 includes the thermosetting resin and the conductive particles scattered in this thermosetting resin. The resin containing portion 420 includes the thermosetting resin. The density of the conductive particles of the resin containing portion 420 is lower than the density of the conductive particles of the conductive particle containing portion 410. For example, the resin containing portion 420 substantially may not include the conductive particles. Further, a viscosity of the resin containing portion 420 is lower than a viscosity of the conductive particle containing portion 410. For example, the viscosity of the conductive particle containing portion 410 and the viscosity of the resin containing portion 420 can be made different from each other when a thermosetting resin included in the conductive particle containing portion 410 and a thermosetting resin included in the resin containing portion 420 are different. In the present embodiment, a thickness of the resin containing portion 420 is thicker than a thickness of the conductive particle containing portion 410. However, a relationship between the thickness of the conductive particle containing portion 410 and the thickness of the resin containing portion 420 is not limited to a relationship according to the present embodiment.

At least the portion of the above first portion of the resin composition 400 is the conductive particle containing portion 410 of the resin composition 400, and at least the portion of the above second portion of the resin composition 400 is the resin containing portion 420 of the resin composition 400. In this case, the resin containing portion 420 of the resin composition 400 flows out from the first region R1 toward the second region R2, and becomes the second portion 320 of the resin film 300, that is, the protection coating.

In the present modification example, it is not necessary to extend the resin composition 400 to the second region R2. Thus, in comparison with a case where the resin composition 400 is extended to the second region R2, it is possible to make the resin composition 400 which is necessary for forming the resin film 300 smaller, and it is possible to reduce a cost of the resin composition 400. However, the resin composition 400 may be extended to the second region R2.

In the present modification example also, after the resin containing portion 420 of the resin composition 400 flows out from the first region R1 toward the second region R2, the resin composition 400 may be pressed by at least one of the terminal 142 of the first electronic component 10 and at least a portion of the second electronic component 20 such that the thickness of the portion of the resin composition 400 which overlap the terminal 142 and the second electronic component 20 when viewed from the predetermined direction D becomes thinner than the thickness of a portion of the resin composition 400 which does not overlap the substrate 100 or the terminal 142 and overlaps the second electronic component 20 when viewed from the predetermined direction D. This allows, as shown in FIG. 2, the second portion 320 of the resin film 300 to cover the portion of the side surface of the substrate 100.

In the present modification example, the resin composition 400 is used such that the conductive particle containing portion 410 is oriented to the first electronic component 10, and that the resin containing portion 420 is oriented to the second electronic component 20. However, the resin composition 400 may be used such that the conductive particle containing portion 410 is oriented to the second electronic component 20, and that the resin containing portion 420 is oriented to the first electronic component 10.

Hitherto, the embodiment and examples are described with reference to the drawings. However, these are just examples of the present invention, and various other configurations may be employed.

This application claims priority from Japanese Patent Application No. 2020-020809, filed on Feb. 10, 2020, the disclosure of which is incorporated by reference in its entirety.

### REFERENCE SIGNS LIST

10 first electronic component
20 second electronic component
30 electronic device
100 substrate
102 first surface
104 second surface
140 organic EL element
142 terminal
300 resin film
310 first portion
320 second portion
330 third portion
400 resin composition
400A first layer
400B second layer
402 third surface
404 fourth surface
410 conductive particle containing portion
420 resin containing portion
D predetermined direction
R1 first region
R2 second region

1. An electronic device comprising:
a first electronic component having a terminal and a substrate having the terminal;
a second electronic component at least a portion of which overlaps the terminal of the first electronic component; and
a resin film electrically connecting the terminal of the first electronic component and the second electronic component,
wherein the resin film comprises:
a first portion overlapping the terminal and the second electronic component when viewed from a direction perpendicular to a first surface of the substrate; and
a second portion which does not overlap the substrate or the terminal, and overlaps the second electronic component when viewed from the direction perpendicular to the first surface of the substrate.

2. The electronic device according to claim 1,
wherein the resin film comprises a cured product of a resin composition which continues across the first portion and the second portion.

3. The electronic device according to claim 1,
wherein the first portion of the resin film comprises conductive particles, and
wherein a density of the conductive particles of the second portion of the resin film is lower than a density of the conductive particles of the first portion of the resin film.

4. The electronic device according to claim 3,
wherein the second portion of the resin film substantially does not comprise the conductive particles.

5. The electronic device according to claim 1,
wherein a conductivity of the second portion of the resin film is lower than a conductivity of the first portion of the resin film in a direction perpendicular to the first surface of the substrate.

6. The electronic device according to claim 1,
wherein the second portion of the resin film covers a portion of a side surface of the substrate.

7. The electronic device according to claim 1,
wherein the first electronic component is a light-emitting device comprising an organic EL element, and
wherein the second electronic component is FPC.

8. A method for manufacturing an electronic device, the method comprising:
causing a terminal of a substrate of a first electronic component and at least a portion of a second electronic component to overlap each other with a resin composition interposed therebetween; and
electrically connecting the terminal of the first electronic component and the second electronic component through a resin film formed by curing the resin composition,
wherein in the step of causing the terminal of the first electronic component and at least the portion of the second electronic component to overlap each other, when viewed from a direction perpendicular to a first surface of the substrate, a first portion of the resin composition is overlapped with the terminal and the second electronic component, and a second portion of the resin composition is not overlapped with the substrate or the terminal and is overlapped with the second electronic component.

9. A method for manufacturing an electronic device, the method comprising:
causing a terminal of a substrate of a first electronic component and at least a portion of a second electronic component to overlap each other with a resin composition interposed therebetween; and
electrically connecting the terminal of the first electronic component and the second electronic component through a resin film formed by curing the resin composition,
wherein in the step of causing the terminal of the first electronic component and at least the portion of the second electronic component to overlap each other, when viewed from a direction perpendicular to a first surface of the substrate, a first portion and a second portion of the resin composition which have different viscosities are overlapped with each other, and the first portion and the second portion of the resin composition are overlapped with the terminal and the second electronic component.

10. The method for manufacturing an electronic device according to claim 8,
wherein at least a portion of the first portion of the resin composition is a conductive particle containing portion comprising conductive particles, and
wherein at least a portion of the second portion of the resin composition is a resin containing portion which has a density of the conductive particles lower than a density of the conductive particles of the conductive particle containing portion.

11. The method for manufacturing an electronic device according to claim 9,
wherein at least a portion of the first portion of the resin composition is a conductive particle containing portion comprising conductive particles, and
wherein at least a portion of the second portion of the resin composition is a resin containing portion which has a density of the conductive particles lower than a density of the conductive particles of the conductive particle containing portion, and a viscosity lower than a viscosity of the conductive particle containing portion.

12. The method for manufacturing an electronic device according to claim 10,
wherein the resin containing portion of the resin composition substantially does not comprise the conductive particles.

13. The method for manufacturing an electronic device according to claim 8, the method further comprising:
pressing the resin composition by at least one of the terminal of the first electronic component and at least the portion of the second electronic component such that a thickness of a portion of the resin composition which overlaps the terminal and the second electronic component when viewed from a direction perpendicular to the first surface of the substrate is thinner than a thickness of a portion of the resin composition which does not overlap the substrate or the terminal and overlaps the second electronic component when viewed from the direction perpendicular to the first surface of the substrate.

14. The method for manufacturing an electronic device according to claim 8,
wherein the first electronic component is a light-emitting device comprising an organic EL element, and
wherein the second electronic component is FPC.
